(19) United States
(12) Patent Application Publication
(10) Pub. No.: US 2022/0149216 A1
(43) Pub. Date: May 12, 2022

(54) AN ADVANCED PROCESSING ELEMENT AND SYSTEM

(71) Applicant: NewSouth Innovations Pty Limited, UNSW, Sydney, New South Wales (AU)

(72) Inventors: Andrew Dzurak, UNSW, Sydney, New South Wales (AU); Chih-Hwan Henry Yang, UNSW, Sydney, New South Wales (AU); Bas Hensen, UNSW, Sydney, New South Wales (AU); Wister Huang, UNSW, Sydney, New South Wales (AU); Arne Laucht, UNSW, Sydney, New South Wales (AU)

(21) Appl. No.: 17/427,368

(22) PCT Filed: Jan. 31, 2020
(86) PCT No.: PCT/AU2020/050066

§ 371 Date: Jul. 30, 2021

(30) Foreign Application Priority Data
Jan. 31, 2019 (AU) 2019900297

(51) Int. Cl. H01L 31/0352; H01L 21/283

(52) U.S. Cl. CPC H01L 31/035209; H01L 21/283

(57) ABSTRACT

A processing element for a quantum processing apparatus is disclosed. The processing element includes: a silicon substrate; a dielectric material, wherein the silicon substrate and the dielectric material form an interface; an electrode formed on the dielectric material for isolating one or more electrons in the silicon substrate to form a quantum dot; a group IV atom having a nuclear spin located in the wavefunction of the one or more electrons, the nuclear spin of the group IV atom entangled with the one or more electrons; and a control arrangement for controlling a quantum property of the quantum dot and/or the nuclear spin to operate as a qubit.

### TECHNICAL FIELD

Aspects of the present disclosure are related to a processing element for an advanced processing system, and particularly, but not exclusively, to a quantum processing system and a processing element for a quantum processing system.

### BACKGROUND

The developments described in this section are known to the inventors. However, unless otherwise indicated, it should not be assumed that any of the developments described in this section qualify as prior art merely by virtue of their inclusion in this section, or that those developments are known to a person of ordinary skill in the art.

Large-scale quantum processing systems hold the promise of a technological revolution, with the prospect of solving problems which are out of reach with classical machines. To date, a number of different structures, materials, and architectures have been proposed to implement quantum processing systems and fabricate their basic information units (or quantum bits).

One way of fabricating quantum bits, for example, is to use silicon quantum dots. In this case, quantum dots are formed using an interface between a ²⁸Si substrate and a dielectric material. A confining arrangement is utilized for confining one or more electrons in the silicon substrate to form the quantum dot and a control arrangement (e.g., a gate) is formed on the dielectric material to control the confined electron (e.g., by applying a voltage to tune the electronic spin resonance frequency of the confined electron). One technique for fabricating such quantum dots and processing systems utilizing these quantum dots is described in International Patent Applications PCT/AU2014/000596 and PCT/AU2016/050713, which are incorporated herein in their entirety.

When a number of such quantum dots are fabricated at a suitable distance from each other, quantum information can be moved through the quantum dot array via spin shuttling or exchange mediated coupling of the electrons.

Electron spin-based quantum bits show high control fidelity and can utilise the fabrication technologies that already exist for the manufacture of metal-oxide-semiconductor-field-effect-transistors (MOSFETs), making them a popular choice for semiconductor based quantum bits. However, they may suffer from short coherence times.

Accordingly, an improvement is desirable.

### SUMMARY

According to an aspect of the present disclosure, there is provided a processing element for a quantum processing apparatus, the processing element comprising: a silicon substrate; a dielectric material, wherein the silicon substrate and the dielectric material form an interface; an electrode formed on the dielectric material for isolating one or more electrons in the silicon substrate to form a quantum dot; a group IV atom having a nuclear spin located in the wavefunction of the one or more electrons, where the nuclear spin of the group IV atom is entangled with the one or more electrons; and a control arrangement for controlling a quantum property of the quantum dot and/or nuclear spin of the group IV atom to operate as a qubit.

In some embodiments, the atom may be a ²⁹Si atom. In other embodiments, the atom may be an atom of a group IV isotope that has a nuclear spin. For example, the atom may be a germanium-73 (⁷³Ge) atom having a spin of 9/2. In other examples, the atom may be a carbon-13 (¹³C) atom, a tin-115 (¹¹⁵Sn), tin-117 (¹¹⁷Sn) or tin-119 (¹¹⁹Sn) atom.

In some embodiments, where the atom is a silicon-29 atom, the silicon substrate is an isotopically enriched ²⁸Si substrate. In certain embodiments, the isotopically enriched ²⁸Si substrate contains less than or equal to 800 ppm of ²⁹Si atoms. It will be appreciated that the ²⁹Si atoms can naturally exist in the isotopically enriched ²⁸Si substrate or they can be engineered into a pure ²⁸Si substrate—i.e., located within the wavefunction of a quantum dot electron.

Further, the quantum dot electron wavefunction diameter of the processing element can be less than or about 50 nm. And in some preferred embodiments, this diameter can be less than or about 15 nm.

It will be appreciated that the nuclear spin of the group IV atom can be entangled with the electron of the quantum dot via a several mechanisms. One such mechanism is hyperfine interaction between the electron and the nuclear spin. The strength of the hyperfine interaction can vary depending on the size of waveform diameter of the electron and the location of the group IV atom within the waveform. In some embodiments, the hyperfine interaction between the electron and the group IV atom is between about 100 KHz-1 MHz.

According to another aspect of the present disclosure, there is provided a method of operating a plurality of quantum processing elements, each quantum processing element comprising a silicon substrate, a dielectric material, wherein the silicon substrate and the dielectric material form an interface, an electrode formed on the dielectric material for isolating one or more electrons in the silicon substrate to form a quantum dot, a group IV atom having a nuclear spin located in the wavefunction of the one or more electrons, the nuclear spin of the group IV atom entangled with the one or more electrons, and a control arrangement for controlling a quantum property of the quantum dot and/or the nuclear spin to operate as a qubit. The method includes the step of applying a signal via the control arrangement to control the state of the qubit in a quantum processing element.

In certain embodiments, the method further includes applying a signal via the control arrangement to store information in the qubit. This can include applying the signal to store information in the electron spin of the quantum dot and swapping this information from the electron spin to the nuclear spin of the ²⁹Si atom.

In certain embodiments, the method further includes transferring information from a first processing element of the plurality of processing elements to a second processing element of the plurality of processing elements. This includes swapping the information from the nuclear spin of the group IV atom of the first processing element to the electron spin of the first processing element, transporting the electron spin from the first processing element to the quantum dot of the second processing element, causing the transported electron spin to entangle with the nuclear spin of the group IV atom of the second processing element, and swapping the quantum information from the transported electron spin to the nuclear spin of the group IV atom of the second processing element.

According to yet another embodiment, a method for manufacturing an advanced processing apparatus is disclosed. The method comprises the steps of: manufacturing a plurality of processing elements by: providing a silicon substrate; comprising a ²⁸Si layer; forming a dielectric layer in a manner such that the dielectric layer and the ²⁸Si layer form an interface; forming a plurality of electrodes suitable to isolate one or more electrons about the interface to define a plurality of quantum dots; locating one or more group IV atoms having nuclear spin in the wavefunction of the one or more electrons such that the nuclear spins of the one or more group IV atoms entangles with the electrons of the quantum dots such that the pair of quantum dots and nuclear spins operate as qubits; forming a plurality of control members comprising switches arranged to interact with the plurality of electrodes; and forming a plurality of control lines; each control line being connected to one or more control members to enable simultaneous operation of the plurality of processing elements; wherein the plurality of electrodes, control members and control lines are formed by using a silicon metal-oxide-semiconductor manufacturing process.

Also disclosed is a quantum processing apparatus, comprising: a plurality of quantum processing elements arranged in a matrix, each processing element comprising: a silicon substrate and a dielectric material forming an interface, an electrode arrangement suitable to confine one or more electrons in the silicon to form a quantum dot and a nuclear spin entangled to the one or more electrons; a plurality of control members disposed about the processing elements; each control member comprising one or more switches arranged to interact with the electrode arrangement to perform quantum operations with the processing elements; and a plurality of control lines; each control line being connected to a plurality of control members to enable simultaneous operation of a plurality of processing elements.

### BRIEF DESCRIPTION OF DRAWINGS

FIG. 1A is a plan view of a processing element according to some aspects of the present disclosure.

FIG. 1B is a cross-sectional view of the processing element of FIG. 1A.

FIG. 2A is a cross-sectional view of a quantum device according to some aspects of the present disclosure.

FIG. 2B is a plan view of the quantum device of FIG. 2A.

FIG. 3 is a schematic circuit representation showing transport of quantum information.

FIG. 4A is a chart illustrating a double quantum dot stability diagram showing charge states of each quantum dot vs. gate bias.

FIG. 4B is a chart illustrating a nuclear spin readout bias sequence.

FIG. 5 is a chart illustrating a frequency scan for a nuclear spin readout.

FIG. 6A is a chart illustrating reservoir-based readout of electron spin-up probability for 5 frequency scans.

FIG. 6B is a chart illustrating measured electron spin-up probability for a frequency scan after subtracting the average of the two resonance peaks.

FIG. 7A is a chart showing Rabi oscillations of a nuclear spin.

FIG. 7B is a Rabi chevron pattern for an unloaded quantum dot.

FIG. 7C is a Rabi chevron pattern with a spin-down electron loaded into the quantum dot.

FIG. 8A is a chart showing nuclear spin T₂* and T₂^{Hahn} measurements for different charge configurations of a double quantum dot.

FIG. 8B is a table showing the measured values for the coherence times and decay exponents for the nuclear spin, extracted from measurements in FIG. 8A.

FIG. 9 is a schematic diagram illustrating an example entanglement sequence for entangling an electron and nuclear spin according to some embodiments of the present disclosure.

FIGS. 10A-10F show state tomography of a Bell state.

While the invention is amenable to various modifications and alternative forms, specific embodiments are shown by way of example in the drawings and are described in detail. It should be understood, however, that the drawings and detailed description are not intended to limit the invention to the particular form disclosed. The intention is to cover all modifications, equivalents, and alternatives falling within the spirit and scope of the present invention as defined by the appended claims.

### DETAILED DESCRIPTION

Typically, the surface silicon layer in which the gate-based quantum dots are formed is isotopically enriched to predominately contain ²⁸Si atoms, which are known to have no nuclear spin of their own and therefore allow for long coherence times in the quantum dots thus formed. Even isotopically enriched silicon typically includes a small amount of ²⁹Si atoms. These ²⁹Si atoms have a nuclear spin and can sometimes affect the coherence times of quantum dots.

The inventors of the present application have however found that the nuclear spin of a ²⁹Si atom can intimately interact with a nearby quantum dot and specifically with the electron spin of the nearby quantum dot (e.g., via hyperfine coupling) such that the pair of nuclear spin and quantum dot can form a quantum bit (or qubit).

Electron spins typically have poor information storage capabilities (e.g., an electron spin can generally store information for 5-10 microseconds) but they are very mobile and can be used to move information about in a quantum processing system. On the other hand, nuclear spins have good storage capabilities (e.g., a nuclear spin can typically store information for 5-10 milliseconds) but nuclear spins are fixed in the lattice and immobile and are generally not suitable for transferring information.

In the present disclosure, by combining a quantum dot with a ²⁹Si atom, the properties of electron and nuclear spins can be utilized together to form a processing element such that the resulting processing element has high information storage capabilities and high mobility. In one example, the quantum information may be stored in the nuclear spin until it is ready for manipulation, at which stage the quantum information is swapped back to the electron of the quantum dot.

In order to form such a processing element, the quantum dot needs to be small enough and the density of ²⁹Si atoms needs to be sufficient enough such that there is a strong hyperfine coupling (relative to the electron spin resonance linewidth) between the electron spin of the quantum dot and a nearby ²⁹Si atom. In some embodiments, the wavefunction diameter of the electron in a quantum dot is less than 50 nm and in some preferred embodiments the diameter is about 15 nm or less (e.g., between 8-15 nm). In such cases, the density of ²⁹Si atoms in the silicon substrate can be between 50-800 ppm.

It will be appreciated that in some cases, e.g., when the density of ²⁹Si atoms is low or naturally non-existent in the silicon substrate (e.g., if it is pure ²⁸Si substrate), the ²⁹Si atoms can be precisely placed within the wavefunction of the electron(s) of a quantum dot (e.g., via ion implantation) such that they entangle with the electron(s).

The strength of the hyperfine interaction between the electron and nuclear spins is set by the size of the wavefunction of the electron in the quantum dot and the placement of the ²⁹Si atoms within that wavefunction. The stronger the quantum dot is confined (i.e., the smaller the size of the quantum dot), the smaller the wavefunction of its electron and larger the hyperfine coupling between the electron and a nuclear spin located in the wavefunction of the electron.

Accordingly, it will be appreciated that if the quantum dots are too large, the wavefunction of the quantum dots would be large, resulting in a smaller hyperfine interaction between the electron and nuclear spins located in the wavefunction of the electron. Similarly, if the density of ²⁹Si is high, a large number of ²⁹Si atoms may be located in the wavefunction of the electron which can act as background noise and reduce the coherence time of the quantum dot. Alternatively, if the density of ²⁹Si is low and the quantum dot is very small, a ²⁹Si atom may not be located in the small wavefunction of the electron and therefore may not be able to entangle with the electron spin of the quantum dot. Accordingly, a balance between the quantum dot size and ²⁹Si atom density is important.

In order to allow entanglement between the ²⁹Si nuclear spin and quantum dot electron spin states and operate the pair as a qubit, specific operational frequencies should be used. In addition, for the qubit to be able to transfer information along a quantum processing system, the hyperfine coupling between the electron and nuclear spins of the qubit should be such that the movement of quantum information through the quantum dot array via spin shuttling or exchange mediated coupling is allowed. For example, the hyperfine coupling between the electron and nuclear spins could be weaker than the quantum dot inter-dot coupling.

It will be appreciated that the qubit thus formed can be used to form nuclear spin-based quantum processing systems or electron spin-based quantum processing systems. Further, the resulting device can function as a memory device for storing quantum information or as an information processing device, or both.

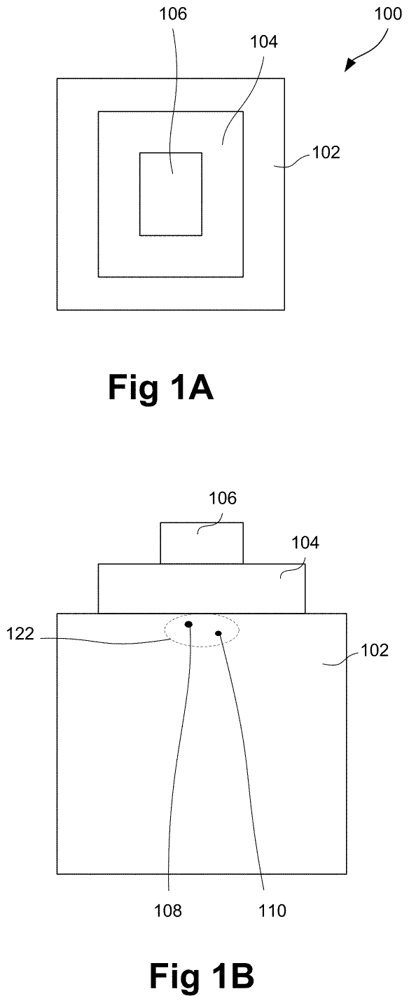

Referring to FIG. 1, a processing element 100 in accordance with an embodiment of the present disclosure is shown in plan (FIG. 1A) and side cross sectional (FIG. 1B) views. The processing element 100 may be implemented as a qubit for a quantum computer processing a plurality of these processing elements.

In this embodiment, the processing element 100 comprises a silicon substrate 102 and a dielectric 104. The silicon substrate 102 in this example is isotopically enriched silicon having ²⁹Si atoms density of less than or equal to 800 ppm and the dielectric 104 is silicon dioxide. The isotopically enriched silicon may be an epitaxial layer grown on a conventional silicon substrate. It will be appreciated that in other examples, the density of ²⁹Si atoms in the silicon substrate may be different and outside this range. For example, in some cases the silicon substrate may have a lower density than 50 ppm and ²⁹Si atoms may be engineered or fabricated into the silicon substrate such that they are located in and around the wavefunction of the electron(s) in the quantum dot.

A gate electrode 106 is provided and is operable to form a quantum dot proximate the Si/SiO₂ interface. The gate electrode 106 is also arranged to modify a quantum property of the quantum dot. In one example, the quantum dot includes one or more electrons 108 and the electrode gate 106 is configured to control the effective g-factor of the electrons 108. Throughout this specification, the term “effective g-factor”, is used broadly to indicate a ratio between the spin resonance frequency for the spin system and the DC magnetic field.

In addition to controlling a quantum property of the quantum dot, the gate electrode 106 may also be used to directly control the spin of the electrons 108 using an AC electric or magnetic field.

In order to form electrons 108 in the quantum dot, sufficiently positive voltages are applied to the gate electrode 106. This causes electrons in the area below the gate 106 (see FIG. 1B and area 122) to be isolated. FIG. 1B illustrates a single electron is isolated in area 122, thus forming an isolated quantum dot. The processing element 100 further includes a ²⁹Si atom 110 located within the wavefunction of the electron 108 such that the nuclear spin of the ²⁹Si atom is entangled with the electron 108 of the quantum dot. A single qubit can thus be encoded in the spin of the isolated electron 108 and/or entangled nuclear spin 110.

It will be appreciated that the gate electrode 106 is also used to control a quantum property of the ²⁹Si atom and/or control the spin of the nucleus. In addition, the gate electrode 106 can be used to control the spin of the ²⁹Si nucleus (e.g., using similar techniques to those used for electron spin resonance), swap quantum information between the nucleus and the electron and/or between two such processing elements.

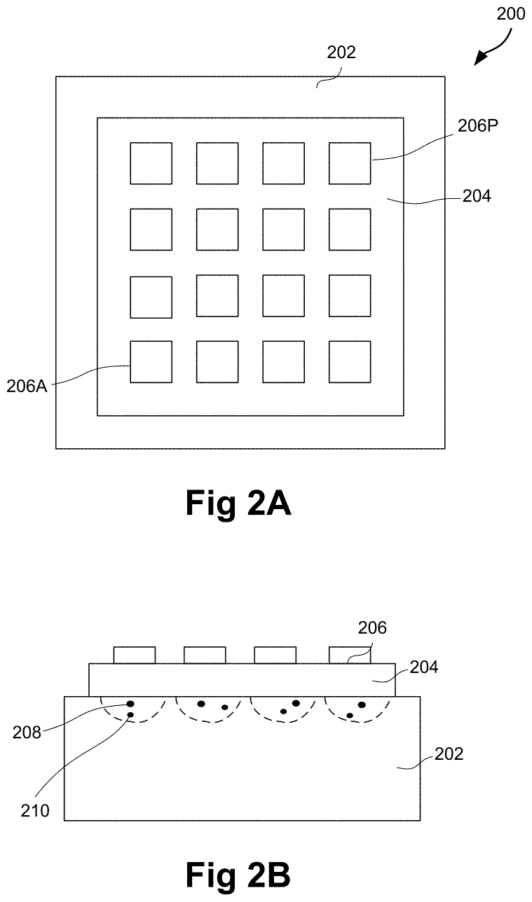

FIG. 2 illustrates a cross-sectional view (FIG. 2A) and plan view (FIG. 2B) of a quantum device 200 in accordance with an embodiment of the present disclosure. The device 200 may be a quantum memory for storing information, a quantum processor, or a combination of a quantum memory and processor.

The quantum device 200 includes an isotopically enriched ²⁸Si layer 202 topped by a dielectric layer 204. Gate electrodes 206A-206P are formed on the dielectric layer 204. When a sufficiently large positive voltage is applied via the gate electrodes 206, one or more electrons 208 are isolated in the area under each gate electrode 206. These isolated electrodes 208 then entangle with one or more ²⁹Si atoms 210 located in the wavefunction of each of the electrons 208 to form entangled electron and nuclear spins, where each combination of quantum dot and ²⁹Si atom can be used to encode a qubit.

In the illustrated example, an array of 4×4 qubits can be encoded in the quantum device 200. In this case, an electromagnetic field may be applied to the gate electrodes 206 to control inter quantum dot coupling and the hyperfine coupling between the electron and nuclear spins in a particular processing element.

In certain embodiments, the gate electrodes 206 and hence the quantum dot location can be lithographically defined anywhere on the quantum device 200 providing flexibility in the device design. Typically, however, the requirements for forming such processing element (i.e., optimal dot size and ²⁹Si atom density, and trade-off between the hyperfine coupling and inter-dot coupling) would be satisfied with a quantum device design having gate widths of less than 30 nm fabricated on top of a 800 ppm isotopically enriched silicon substrate, separated by a high-quality thermally-grown oxide.

### Entanglement of Nuclear and Electron Spin

The electron spin resonance (ESR) frequency (f_{ESR}) of an entangled nuclear and electron spin is—

f_{ESR}=|γₑB|+A/2, when the nuclear spin is up

f_{ESR}=|γₑB|−A/2, when the nuclear spin is down

Where γₑ is the electron gyromagnetic ratio, A is the electron-nuclear hyperfine interaction and B is the DC magnetic field. Further, spin up can be defined as a spin being parallel to, or aligned with, the DC magnetic field (B), whereas spin down can be defined as anti-parallel, or aligned opposite to, the DC magnetic field.

Performing a spin inversion with a pi-pulse on one of these frequencies implements a 2-qubit operation known as the controlled-not (CNOT) gate, which can be used to generate entanglement.

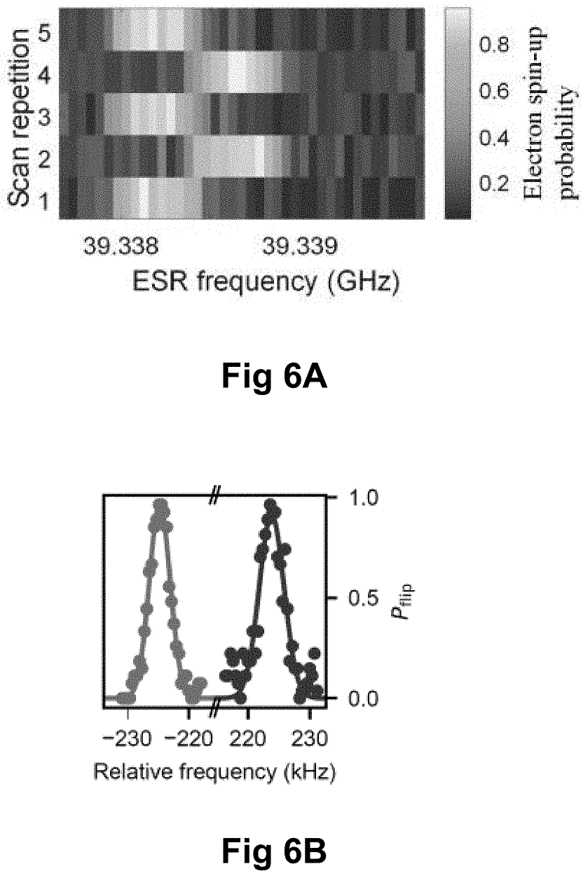

FIG. 6A is a chart illustrating nuclear magnetic resonance (NMR)-pi pulse (i.e., nuclear spin rotations) between 5 spin inversion repetitions. In particular, it shows a reservoir-based readout of electron spin-up probability for 5 frequency scans. The nuclear spin is rotated between each frequency scan resulting in the ESR frequency jumping between two distinct values.

FIG. 6B is a chart illustrating measured electron spin-up probability for a frequency scan after subtracting the average of the two resonance peaks. The relative frequency shows the hyperfine coupling is about 450 kHz.

FIG. 9 illustrates an example entanglement sequence for entangling an electron and nuclear spin. In particular, the figure illustrates a sequence of gates used for the entanglement. As shown in the figure, state preparation (i.e., the first stage) proceeds with pi/2(x) for the nuclear spin followed by a CNOT gate (X) on the electron spin. State projection and readout can be performed via a series of pi/2 gates on both electron and nuclear spin with different phases. Dehollain, J. P. et al., “Bell's inequality violation with spins in silicon”. Nat Nano 11, 242-246 describes a detailed example of electron-nuclear entanglement generation via conditional rotations and it is incorporated herein in its entirety.

### Nuclear Spin Control

As noted previously, the gate electrode can be used to control the nuclear spin of the ²⁹Si atom. In particular, the nuclear spin can be controlled via an AC magnetic field, in the same way electron spin resonance is performed on the electron of the quantum dot.

Depending on whether the quantum dot is loaded with an electron or not, the resonance frequency will be either

|γ_N B|, when no electron is loaded

|γ_N B|+A/2 when the electron is loaded with spin down

|γ_N B|−A/2 when the electron is loaded with spin up

Typical rotation Rabi frequencies that can be obtained are between 1-10 kHz.

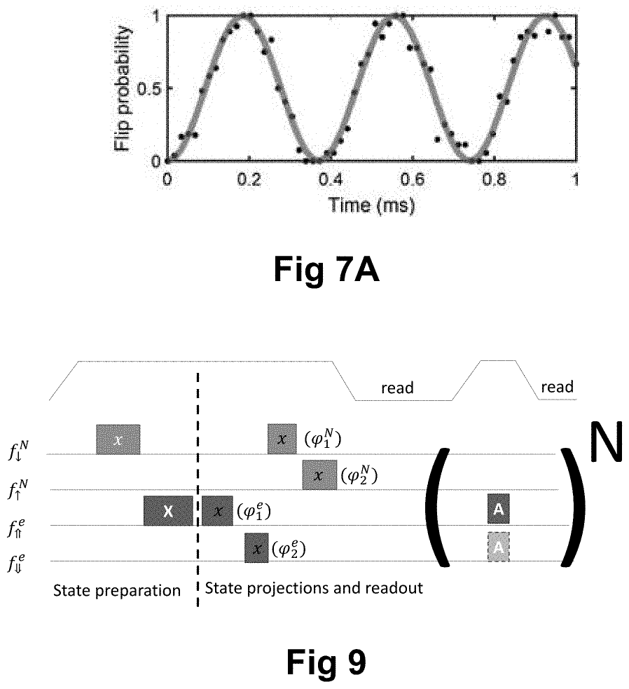

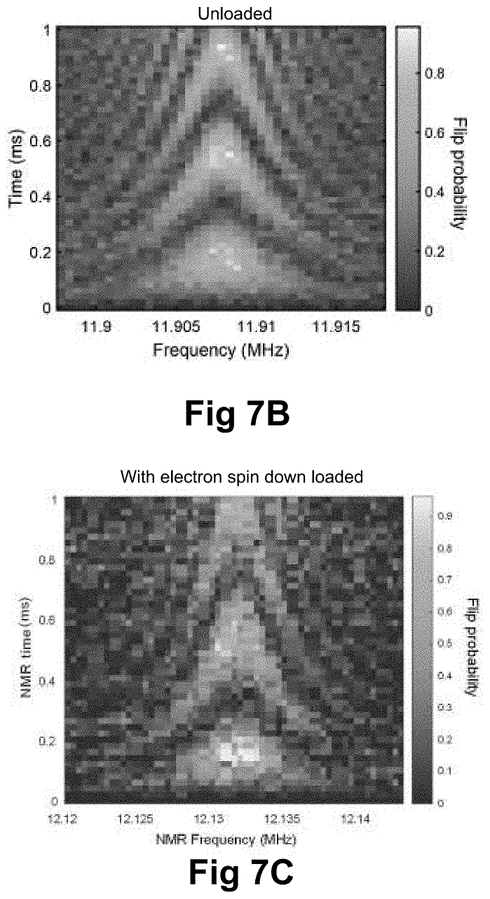

FIG. 7A is a chart illustrating Rabi oscillations of the nuclear spin demonstrating nuclear spin control with very high readout fidelity of >99%.

FIG. 7B is chart illustrating Rabi chevron pattern for an unloaded quantum dot (i.e., without an electron loaded into the quantum dot). The Rabi oscillations are shown vs frequency detuning in this figure.

FIG. 7C is a chart illustrating Rabi chevron pattern for a quantum dot with a spin-down electron loaded into the quantum dot. The shift in resonance frequency gives the hyperfine coupling of 448.5+/−0.1 kHz.

### Storing Quantum Information

As noted previously, nuclear spins have longer quantum memory storage capabilities than electron spins. To take advantage of this, the processing elements of FIGS. 1 and 2 can be utilized such that quantum information is stored in the nuclear spin until it is required for a processing function.

To this end, once quantum information is encoded on the electron spin of a quantum dot using the mechanisms described in International Patent Applications PCT/AU2014/000596 and PCT/AU2016/050713, a memory operation is performed to map the qubit information encoded in the electron spin state onto the nuclear spin state.

This operation, known as a SWAP operation, can be implemented with three controlled rotations and typically includes three stages—initialisation, transfer and recovery. In one embodiment, nuclear initialisation in the spin up state is achieved with a sequence of microwave and/or RF pulses. Starting from the spin down electron state and the nuclear spin in an unknown state, the microwave pulse flips the electron to the spin up state only if the nucleus is in the spin up state as well. In that case, the subsequent RF pulse is off-resonance with the nucleus and leaves the nucleus in the target spin up state. Conversely, if the nucleus is initially spin down, the microwave pulse is off-resonance with the electron, and the subsequent RF pulse flips the nucleus from spin down to spin up state. With one more electron readout/initialization step, the system is unconditionally prepared such that the electron is in the spin down state and the nucleus is in the spin up state.

In the transfer stage, to transfer the quantum information from the electron to the nucleus, a first RF pulse conditionally shifts the spin down component of the electron spin state onto the spin down component of the nucleus, creating a double quantum coherence between the electron and nuclear spin ups or spin downs if the electron possessed a spin up component. The subsequent microwave pulse conditional on the nuclear spin up subspace, translates the spin up electron and nuclear component onto the electron spin down nucleus spin up state, leaving the nuclear spin with all the quantum information and the electron spin in the spin down eigenstate. The ‘transfer’ operation of the memory protocol is now complete and the quantum information may be left in the nuclear state for the desired wait time before reversing the order of the pulses (‘recovery’ sequence) to bring the quantum information back to the electron state.

### Nuclear Spin State Readout

As noted previously, in addition to isolating electrons, electrical signals can be applied to the electrodes 106/206 to perform selected operations on the processing elements and/or readout a quantum state of the processing element.

In certain embodiments, the nuclear spin state readout may be performed by performing electron spin resonance (ESR) on the electron of the quantum dot using, e.g., microwave pulses. These microwave pulses in one example may be delivered by an on-chip broadband planar transmission line (not shown).

In response to the microwave pulses, the system will exhibit two possible ESR frequencies depending on the state of the nuclear spin—i.e., for a nuclear spin up, the processing element will exhibit an ESR frequency of ESR plus half the hyperfine interaction (γₑB+A/2) and for a nuclear spin down, the processing element will exhibit an ESR frequency of ESR minus half the hyperfine interaction (γₑB−A/2). Depending on the detected ESR, the state of the nuclear spin can therefore be determined.

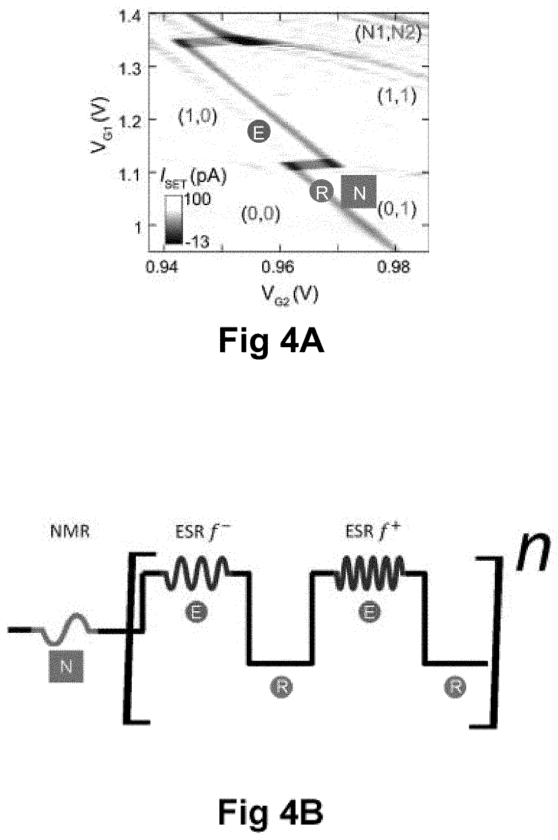

FIG. 4A illustrates a double quantum dot stability diagram showing the charge states of each dot in relation to a bias applied through the gate electrode. The bias configuration for different stages of nuclear spin readout are shown in FIG. 4A, where N indicates the nuclear magnetic resonance RF signals, E indicates the electron spin resonance microwave signal and R indicates readout points.

Further, FIG. 4B illustrates the nuclear spin readout bias sequence showing nuclear magnetic resonance RF signals (N), electron spin resonance microwave signal (E) and readout points (R).

FIG. 5 is a frequency scan showing a resonance observed when applying a 11.908 MHz RF signal and 1.42 T magnetic field, giving a gyromagnetic ratio |γ_{N}|=8.83 MHz/T, consistent with ²⁹Si.

### Moving Information

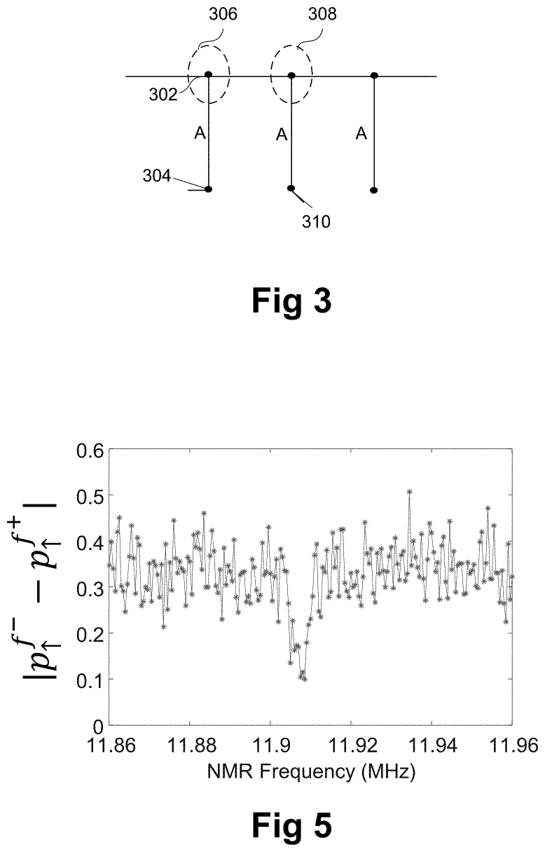

As noted previously, nuclei, therefore nuclear spins, are generally immobile whereas electrons, and therefore electron spins are very mobile and can be shuttled along the quantum device 200 to transport information to other circuit nodes. FIG. 3 is a schematic circuit representation showing exchange coupled quantum dots and the shuttling of a single electron 302 to transport quantum information.

Typically, in donor-electron spin systems, when the electron is unloaded from the donor, the nuclear coherence of the donor is destroyed. This is because the ionisation rate of unloading an electron is slow relative to the typical hyperfine coupling between the donor and electron, which results in a random phase shift of the nuclear spin state depending on the random time the electron was ionized.

However, because in the presently disclosed system it is possible for the electron to tunnel between two neighbouring quantum dots via spin shuttling or exchange mediated coupling, the tunnel rate for unloading an electron from the quantum dot is much higher than the ionisation rate of electron-donor systems. In the presently disclosed system, it is therefore possible to retain the nuclear spin coherence when unloading the electron.

This is important when the electron is used as a mediator of entanglement between nuclear spins in different quantum dots. To do this, the electron 302 can first be entangled with a nuclear spin 304 in a first quantum dot 306. The electron 302 is then transferred to a second quantum dot 308, where it can be entangled with a second nuclear spin 310. If the state of the electron spin of the second quantum dot is measured at this time, it will be determined that the two nuclear spins 304 and 310 are projected onto an entangled state, even though the two nuclear spins did not interact directly. In this manner, information can be shuttled across the quantum device 200 from one quantum dot to the next.

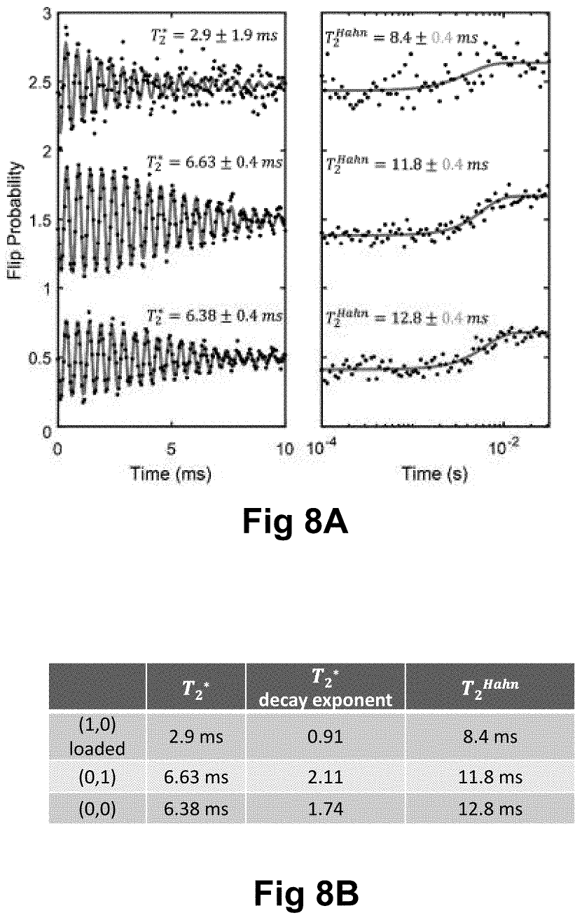

FIG. 8 illustrates the nuclear spin coherence properties of a ²⁹Si atom. In particular, FIG. 8A is a chart illustrating the nuclear spin T₂* and T₂^{Hahn} measurements for different charge configurations of a double dot (offset by 1 for each trace). Either 1 or 0 electrons are loaded into each dot.

FIG. 8B is a table that illustrates the measured values for the coherence times and decay exponents for the nuclear spin, extracted from measurements in FIG. 8a.

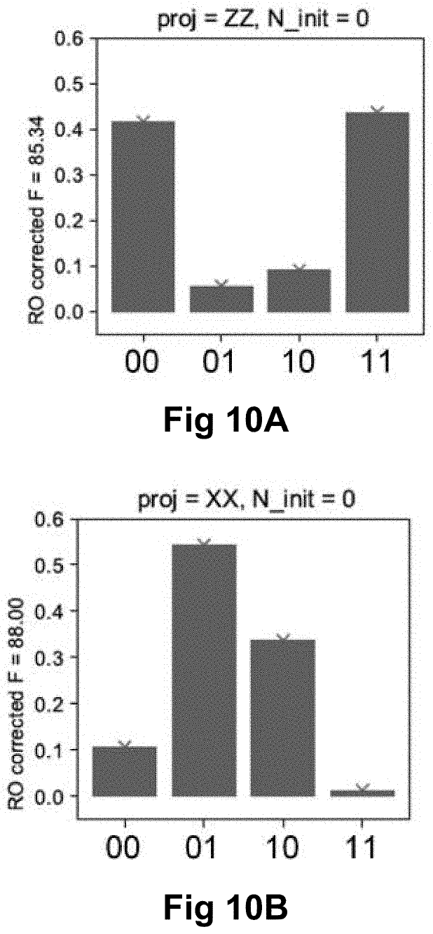

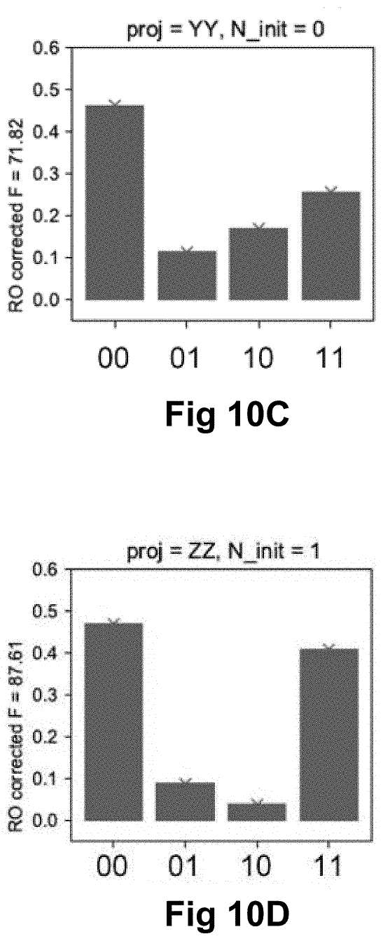

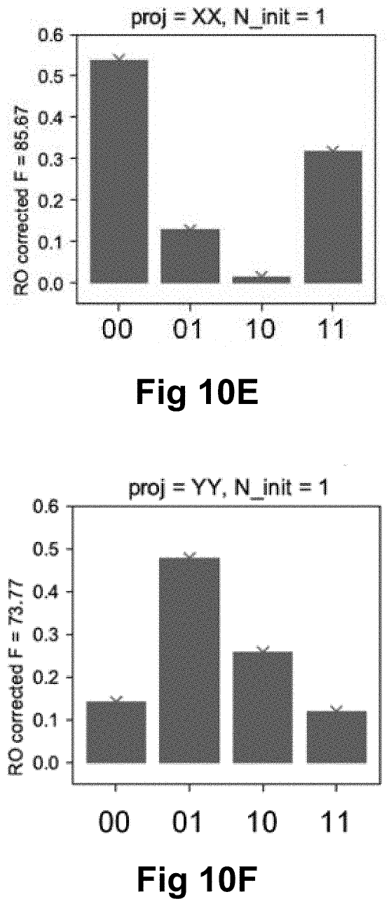

FIG. 10 includes multiple charts, with each chart showing the state tomography of a Bell state. In particular, charts 10A-10C show the state tomography of the Bell state with nuclear spin-down initialization and charts 10D-10F show the state tomography of the Bell state with nuclear spin-up initialization. Correlations/anti-correlations are observed in the XX, YY and ZZ basis. Fidelity estimates are F=72±3% for spin-down initialization and F=80±3% for spin-up initialization.

It will be appreciated that the architectures described in the embodiments above utilize an electron in the quantum dot that is entangled with the nucleus of a ²⁹Si atom. In other embodiments, the quantum dot can be configured to confine holes instead of electrons and the holes can be entangled with the ²⁹Si atoms.

### Other Group IV Elements

In some embodiments, instead of using ²⁹Si atoms and entangling their nuclear spins with nearby quantum dots, any other (stable) group IV atoms (e.g., Carbon, Germanium, Tin or Lead) that have a nuclear spin may be utilized. In one example, the carbon-13 (¹³C) isotope may be utilized. In another example, a Germanium-73 (⁷³Ge) isotope may be utilized. Tin has a number of stable isotopes with nuclear spins, such as Tin-115 (¹¹⁵Sn), tin-117 (¹¹⁷Sn), Tin-119 (¹¹⁹Sn) and any of these isotopes of tin may be utilized instead of ²⁹Si atoms.

The atoms of one or more of these elements can be implanted with low energy to place them at a shallow depth and therefore within the wavefunction of a nearby quantum dot (similar to the way described for the ²⁹Si atoms above). The nuclear spin of the atom could then be entangled with the electron spin of the nearby quantum dot(s) via hyperfine coupling.

The carbon and tin isotopes have a spin of ½ (similar to ²⁹Si) and therefore function in the same manner as the ²⁹Si atoms. The Germanium isotope has a spin of 9/2. This means that the germanium nuclear spin has 10 states that can be used for quantum computation as opposed to the 2 states available for silicon, carbon, and tin atoms.

One example method for artificially introducing one or more group IV atoms in a silicon substrate is described in U.S. Pat. No. 7,002,166, titled “method and system for single ion implantation”, which is incorporated herein in its entirety. Although implanting techniques are described in that patent with respect to Phosphorus atoms, those techniques can be utilized (with minor modifications) to precisely implant carbon, silicon, germanium or tin atoms in a silicon substrate.

The term “comprising” (and its grammatical variations) as used herein are used in the inclusive sense of “having” or “including” and not in the sense of “consisting only of”.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A processing element for a quantum processing apparatus, the processing element comprising:
a silicon substrate;
a dielectric material, wherein the silicon substrate and the dielectric material form an interface;
an electrode formed on the dielectric material for isolating one or more electrons in the silicon substrate to form a quantum dot;
a group IV atom having a nuclear spin located in the wavefunction of the one or more electrons, the nuclear spin of the group IV atom entangled with the one or more electrons; and
a control arrangement for controlling a quantum property of the quantum dot and/or the nuclear spin to operate as a qubit.

2. The processing element of claim 1, wherein the group IV atom is a silicon-29 (²⁹Si) atom.

3. The processing element of claim 2 wherein the silicon substrate is an isotopically enriched ²⁸Si substrate.

4. The processing element of claim 3, wherein the isotopically enriched ²⁸Si substrate contains less than or equal to 800 ppm of ²⁹Si atoms.

5. The processing element of claim 1, wherein the group IV atom is an isotope of a group IV element having nuclear spin.

6. The processing element of claim 5, wherein the atom is a germanium-73 atom.

7. The processing element of claim 5 or 6, wherein the group IV atom is implanted in the silicon substrate.

8. The processing element of any one of claims 1-7, wherein the quantum dot electron wavefunction diameter is less than around 50 nm.

9. The processing element of any one of claims 1-8, wherein the quantum dot electron wavefunction diameter is less than or equal to 15 nm.

10. The processing element of any one of claims 1-9, wherein the nuclear spin of the group IV atom is entangled with the electron of the quantum dot via a hyperfine interaction.

11. The processing element of claim 10, wherein the hyperfine interaction between the electron and the group IV atom is between 100 KHz-1 MHz.

12. A method of operation of a plurality of quantum processing elements, each processing element comprising a silicon substrate, a dielectric material, wherein the silicon substrate and the dielectric material form an interface, an electrode formed on the dielectric material for isolating one or more electrons in the silicon substrate to form a quantum dot, a group IV atom having a nuclear spin located in the wavefunction of the one or more electrons, the nuclear spin of the group IV atom entangled with the one or more electrons, and a control arrangement for controlling a quantum property of the quantum dot and/or the nuclear spin to operate the quantum dot and/or the nuclear spin as a qubit, the method comprising the step of:
applying a signal via the control arrangement to control the state of the qubit.

13. The method of claim 12, further comprising applying a signal via the control arrangement to store information in the qubit.

14. The method of claim 13, wherein storing information in the qubit comprises:
applying the signal to store information in the electron spin of the quantum dot; and
swapping this information from the electron spin to the nuclear spin of the group IV atom.

15. The method of claim 14 further comprising transporting quantum information from a first processing element of the plurality of processing elements to a second processing element of the plurality of processing elements.

16. The method of claim 15, wherein transporting information from the first processing element to the second processing element comprises:
swapping the quantum information from the nuclear spin of the group IV atom of the first processing element to the electron spin of the first processing element; and
transporting the electron spin from the first processing element to the quantum dot of the second processing element;
causing the transported electron spin to entangle with the nuclear spin of the group IV atom of the second processing element; and
swapping the quantum information from the transported electron spin to the nuclear spin of the group IV atom of the second processing element.

17. The method of claim 16, wherein the electron spin of the first processing element is transported to the quantum dot of the second processing element via spin shuttling or exchange mediated coupling between the quantum dots of the first and second processing elements.

18. A method for manufacturing an advanced processing apparatus comprising the steps of:
manufacturing a plurality of processing elements by:
providing a silicon substrate comprising a ²⁸Si layer;
forming a dielectric layer in a manner such that the dielectric layer and the ²⁸Si layer form an interface;
forming a plurality of electrodes suitable to isolate one or more electrons about the interface to define a plurality of quantum dots;
locating one or more group IV atoms having nuclear spin in the wavefunction of the one or more electrons such that the nuclear spins of the one or more group IV atoms entangles with the electrons of the quantum dots such that the pair of quantum dots and nuclear spins operate as qubits;
forming a plurality of control members comprising switches arranged to interact with the plurality of electrodes; and
forming a plurality of control lines; each control line being connected to one or more control members to enable simultaneous operation of the plurality of processing elements;
wherein the plurality of electrodes, control members and control lines are formed by using a silicon metal-oxide-semiconductor manufacturing process.

19. The processing element of claim 18, wherein at least one of the one or more group IV atoms is a silicon-29 (²⁹Si) atom.

20. The method for manufacturing of claim 18, wherein providing the silicon substrate comprises providing an isotopically enriched ²⁸Si substrate.

21. The method for manufacturing of claim 20, wherein the isotopically enriched ²⁸Si substrate contains less than or equal to 800 ppm of ²⁹Si atoms.

22. The processing element of claim 18, wherein at least one of the one or more group IV atoms is a germanium-73 atom.

23. The processing element of any one of claim 18, 19 or 22, wherein the one or more group IV atoms are implanted in the silicon substrate.

24. The method for manufacturing of any one of claims 18-23, wherein the wavefunction diameter of the electrons in each of the quantum dots is less than around 50 nm.

25. The method for manufacturing of claim 24, wherein the wavefunction diameter of at least one of the electrons in at least one of the quantum dots is less than or equal to 15 nm.

26. The method for manufacturing of any one of claims 18-25, wherein the nuclear spin of the group IV atom is entangled with the electron of the quantum dot via a hyperfine interaction.

27. The method for manufacturing of claim 26, wherein the hyperfine interaction between an electron and the atom is between 100 KHz-1 MHz.

28. A quantum processing apparatus, comprising:
a plurality of quantum processing elements arranged in a matrix, each processing element according to the processing element of claim 1;
a plurality of control members disposed about the processing elements; each control member comprising one or more switches arranged to interact with the processing elements to perform quantum operations with one or more of the plurality of processing elements; and
